(19) United States
(12) Patent Application Publication
(10) Pub. No.: US 2024/0178137 A1
(43) Pub. Date: May 30, 2024

(54) METHOD FOR DETERMINING ANTENNA RULE FOR RADIO-FREQUENCY DEVICE

(71) Applicant: UNITED MICROELECTRONICS CORP., Hsin-Chu City (TW)

(72) Inventors: XINGXING CHEN, Singapore (SG); Ching-Yang Wen, Singapore (SG); Purakh Raj Verma, Singapore (SG)

(73) Assignee: UNITED MICROELECTRONICS CORP., Hsin-Chu City (TW)

(21) Appl. No.: 18/108,024

(22) Filed: Feb. 10, 2023

(30) Foreign Application Priority Data
Nov. 29, 2022 (CN) 202211511074.2

(51) Int. Cl. H01L 23/528; H01L 23/522; H01Q 1/38

(52) U.S. Cl. CPC H01L 23/528; H01L 23/5227; H01Q 1/38

(57) ABSTRACT

A method for determining antenna rule for a radio-frequency (RF) device includes the steps of forming a gate structure on a substrate, forming a source/drain region adjacent to the gate structure, forming a first metal routing on the source/drain region, and then forming a second metal routing on the gate structure. Preferably, a sum of an area of the first metal routing and an area of the second metal routing divided by an area of the gate structure is less than a ratio.

### BACKGROUND OF THE INVENTION

### 1. Field of the Invention

The invention relates to a method for fabricating semiconductor device, and more particularly to a method for determining antenna rule for a radio-frequency (RF) device.

### 2. Description of the Prior Art

As technology evolves, wireless communication is an important part of human life. Various electronic devices, such as smart phones, smart wearable devices, tablets, etc., utilize wireless radio frequency (RF) systems to transmit and receive wireless signals. A low noise amplifier (LNA) and a power amplifier (PA) are necessary amplifying circuits in the wireless RF system. In order to achieve better performance (e.g., linearity), the amplifying circuit requires an appropriate bias point. A common way is to electrically connect a biasing module to the amplifying circuit, so as to utilize the biasing module for providing a bias point for the amplifying circuit.

Nevertheless in conventional fabrication of RF devices, part of metal interconnections connected to the gate structures and/or source/drain regions are often used as antenna for collecting charges and as the area of the metal interconnections increases the charges collected also increase accordingly. As the charges over accumulates, leakage would result and damages the gate dielectric layer made of silicon oxide. Hence how to improve current RF device structures for resolving this issue has become an important task in this field.

### SUMMARY OF THE INVENTION

According to an embodiment of the present invention, a method for determining antenna rule for a radio-frequency (RF) device includes the steps of forming a gate structure on a substrate, forming a source/drain region adjacent to the gate structure, forming a first metal routing on the source/drain region, and then forming a second metal routing on the gate structure. Preferably, a sum of an area of the first metal routing and an area of the second metal routing divided by an area of the gate structure is less than a ratio.

According to another aspect of the present invention, a radio-frequency (RF) device includes a gate structure on a substrate, a source/drain region adjacent to the gate structure, a first metal routing on the source/drain region, and a second metal routing on the gate structure. Preferably, a sum of an area of the first metal routing and an area of the second metal routing divided by an area of the gate structure is less than a ratio.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 illustrate a method for fabricating a RF device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

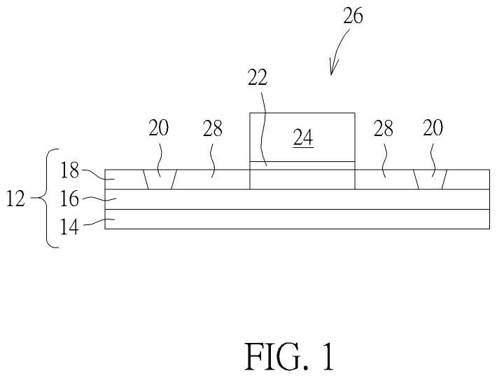

Referring to FIGS. 1-3, FIGS. 1-3 illustrate a method for fabricating a RF device according to an embodiment of the present invention. As shown in FIG. 1, a substrate 12 made of semiconductor material is provided. In this embodiment, the substrate 12 is a silicon-on-insulating (SOI) substrate which preferably includes a first semiconductor layer 14, an insulating layer 16 on the first semiconductor layer 14, and a second semiconductor layer 18 on the insulating layer 16. Preferably, the first semiconductor layer 14 and the second semiconductor layer 18 could be made of same material or different material and could both be made of material including but not limited to for example silicon, germanium, or silicon germanium (SiGe). The insulating layer 16 disposed between the first semiconductor layer 38 and second semiconductor layer 42 preferably includes SiO₂, but not limited thereto.

It should be noted that even though a SOI substrate is chosen as the substrate 12 for the RF device of this embodiment, the substrate 12 could also be made of semiconductor substrate material including but not limited to for example silicon substrate, epitaxial silicon substrate, or silicon carbide substrate, which are all within the scope of the present invention. Next, part of the second semiconductor layer 18 could be removed and a shallow trench isolation (STI) 20 is formed in the second semiconductor layer 18 and an active device could be formed on the second semiconductor layer 18 surrounded by the STI 20 thereafter.

Next, at least an active device could be disposed on the substrate 12, in which the active device could include metal-oxide semiconductor (MOS) transistor, oxide semiconductor field effect transistor (OS FET), fin field effect transistor (FinFET), or other active devices. If a MOS transistor were to be fabricated, the MOS transistor could include elements such as a gate structure 26 made of gate dielectric layer 22 and gate electrode 24 on the substrate 12, a spacer (not shown) adjacent to the sidewalls of the gate structure 26, and a source/drain region 28 in the substrate 12 adjacent to two sides of the spacer.

More specifically, the gate structure 26 could be a polysilicon gate made of polysilicon or a metal gate. Despite the gate structure 26 in this embodiment pertains to be a polysilicon gate made of a gate dielectric layer 22 and a gate electrode 24 made of polysilicon, if the gate structure 26 were to be a metal gate, the gate structure 26 would further include elements such as a high-k dielectric layer, a work function metal layer, and a low resistance metal layer. Preferably, the high-k dielectric layer is selected from dielectric materials having dielectric constant (k value) larger than 4. For instance, the high-k dielectric layer may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBizTa₂O₉, SBT), lead zirconate titanate (PbZrₓTi₁₋ₓO₃, PZT), barium strontium titanate (BaₓSr₁₋ₓTiO₃, BST) or a combination thereof.

The work function metal layer is formed for tuning the work function of the later formed metal gates to be adaptable in an NMOS or a PMOS. For an NMOS transistor, the work function metal layer having a work function ranging between 3.9 eV and 4.3 eV may include titanium aluminide (TiAl), zirconium aluminide (ZrAl), tungsten aluminide (WAI), tantalum aluminide (TaAl), hafnium aluminide (HfAl), or titanium aluminum carbide (TiAlC), but it is not limited thereto. For a PMOS transistor, the work function metal layer having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer and the low resistance metal layer, in which the material of the barrier layer may include titanium (Ti), titanium nitride (TiN), tantalum (Ta) or tantalum nitride (TaN). Furthermore, the material of the low-resistance metal layer may include copper (Cu), aluminum (Al), titanium aluminum (TiAl), cobalt tungsten phosphide (CoWP) or any combination thereof. Since the fabrication of metal gate is well known to those skilled in the art, the details of which are not explained herein for the sake of brevity.

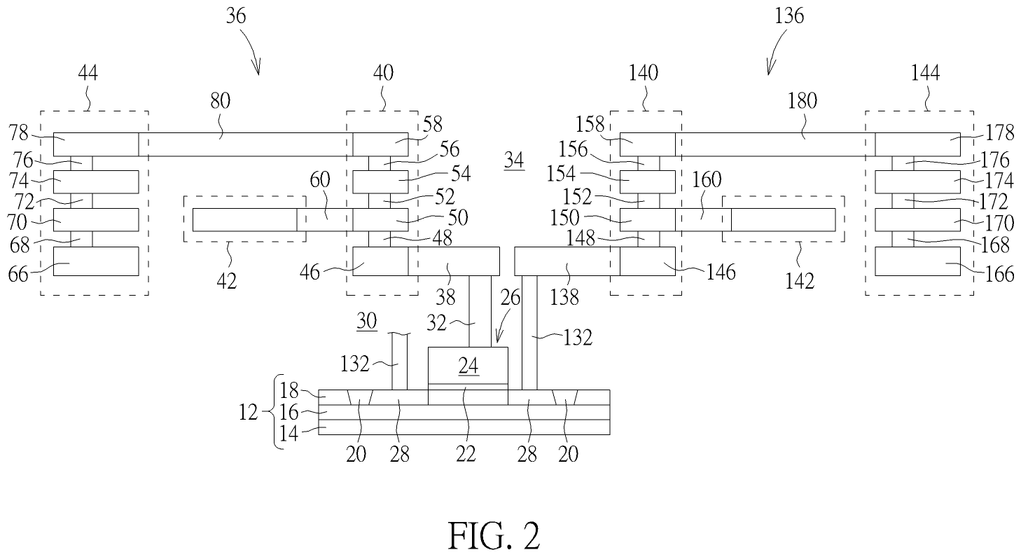

Next, as shown in FIG. 2, an interlayer dielectric (ILD) layer 30 could be formed to cover the MOS transistor or other active devices, and a contact plug formation and/or metal interconnective process could be conducted to form a plurality of contact plugs 32, 132 connecting the source/drain region 28 and gate structure 26, an inter-metal dielectric (IMD) layer 34 disposed on the ILD layer 30, and metal routings 36, 136 in the IMD layer 34 for connecting the contact plugs 32, 132. In this embodiment, the ILD layer 30 and IMD layer 34 could include silicon oxide such as tetraethyl orthosilicate (TEOS) and the contact plugs 32, 132 and metal routings 36, 136 could include Al, Cr, Cu, Ta, Mo, W, or combination thereof, but not limited thereto.

It should be noted that the metal routings 36, 136 formed through metal interconnect process preferably include metal interconnections 38, 138, connection poles 40, 140, antennae 42, 142, and contact pads 44, 144 connected to the gate structure 26 and the source/drain regions 28 adjacent to two sides of the gate structure 26, in which the metal interconnections 38, 138, connection poles 40, 140, antennae 42, 142, and contact pads 44, 144 connected to the gate structure 26 and the source/drain regions 28 are preferably symmetrical structures. For instance, the three sets of metal routings including the metal interconnection 38, the connection pole 40, the antenna 42, and the contact pad 44 connected to the gate structure 26, the metal interconnection 138, the connection pole 140, the antenna 142, and the contact pad 144 connected to the source/drain region 28 on right side of the gate structure 26, and metal interconnection (not shown), connection pole (not shown), antenna (not shown), and contact pad (not shown) connected to the source/drain region 28 on left side of the gate structure 26 are symmetrical structures.

Due to the limit of space, only the metal interconnection 38, the connection pole 40, the antenna 42, and the contact pad 44 connected to the gate structure 26 and the metal interconnection 138, the connection pole 140, the antenna 142, and the contact pad 144 connected to the source/drain region 28 on right side of the gate structure 26 are shown in FIG. 2 while the metal interconnection, the connection pole, the antenna, and the contact pad connected to the source/drain region 28 on left side of the gate structure are omitted in this embodiment.

Referring to the metal routing 36 connected to the gate structure 26 as an example, the metal routing 36 fabricated through the aforementioned metal interconnect process preferably includes the metal interconnection 38, the connection pole 40 connected to the metal interconnection 38, the antenna 42 connected to the connection pole 40, and the contact pad 44 connected to the connection pole 40, in which the contact pad 44 could include a wafer acceptance test (WAT) pad.

Specifically, each of the connection pole 40, the antenna 42, and the contact pad 44 includes one or multiple patterned metal interconnections made of trench conductors and/or via conductors. For instance, the connection pole 40 from bottom to top includes a plurality of patterned metal interconnections 46, 48, 50, 52, 54, 56, 58, in which the bottommost metal interconnection 46 is connected to the same level or first level metal interconnection 38 which further connects to the contact plug 32. The antenna 42 is made of a layer of patterned metal interconnection while the antenna 42 is connected to the same level metal interconnection 50 of the connection pole 40 through another metal interconnection 60. The contact pad 44 from bottom to top includes a plurality of patterned metal interconnections 66, 68, 70, 72, 74, 76, 78 in which the topmost metal interconnection 78 is connected to the same level or fourth level metal interconnection 58 from the connection pole 40 through another metal interconnection 80.

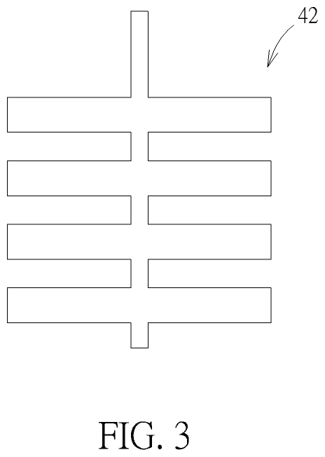

Referring to FIG. 3 at the same time, FIG. 3 illustrates a top view of the antenna 42 according to an embodiment of the present invention. As shown in FIG. 3, the antenna 42 under the top view perspective includes a metal interconnection extending along the Y-direction and a plurality of metal interconnections extending along the X-direction intersecting with the metal interconnections extending along the Y-direction.

Similar to the metal routing 36 connected to the gate structure 26, the metal routing 136 connected to the source/drain region 28 adjacent to right side of the gate structure 26 also includes symmetrical metal interconnection 138 connected to the contact plug 132, a connection pole 140 connected to the metal interconnection 138, an antenna 142 connected to the connection pole 140, and a contact pad 144 or WAT pad connected to the connection pole 140, in which each of the connection pole 140, the antenna 142, and the contact pad 144 includes one or more patterned metal interconnections mad of trench conductors and/or via conductors.

Specifically, the connection pole 140 from bottom to top includes a plurality of patterned metal interconnections 146, 148, 150, 152, 154, 156, 158, in which the bottommost metal interconnection 146 is connected to the same level or first level metal interconnection 138 which further connects to the contact plug 132. The antenna 142 is made of a layer of patterned metal interconnection while the antenna 142 is connected to the same level metal interconnection 150 of the connection pole 140 through another metal interconnection 160. The contact pad 144 from bottom to top includes a plurality of patterned metal interconnections 166, 168, 170, 172, 174, 176, 178 in which the topmost metal interconnection 178 is connected to the same level or fourth level metal interconnection 158 made of trench conductor from the connection pole 140 through another metal interconnection 180.

By using the relationship between the area covered by the metal routings 36, 136 and the area covered by the gate structure 26, it would be desirable to derive a method for determining antenna rule for a RF device. For instance, a sum of the area of the metal routing 136 connected to the source/drain region 28 and the area of the metal routing 36 connected to the gate structure 26 divided by the area of the gate structure 26 itself is less than a ratio, equal to a ratio, or between a range of ratios, such as less than 200, equal to 200, between 150-200, or between 180-220. Preferably, the area of the metal routing 136 connected to the source/drain region 28 could include the area of all the top surfaces of the contact plugs 132 on the same level connected to the source/drain region 28 or the area of all the top surfaces of the metal interconnections 138, 148, 150, 152, 154, 156, 158 on the same level connected to the source/drain region 28. The area of the metal routing 36 connected to the gate structure 26 on the other hand could include the area of all the top surfaces of the contact plugs 32 on the same level connected to the gate structure 26 or the area of all the top surfaces of the metal interconnections 38, 48, 50, 52, 54, 56, 58 on the same level connected to the gate structure 26.

It should be noted even though even though only the metal routing 136 connected to the source/drain region 28 on right side of the gate structure 26 is shown in this embodiment, the area of metal routings connected to the source/drain regions 28 as addressed above preferably includes all the contact plugs and/or all the metal interconnections of the metal routings 136 connected to source/drain regions 28 adjacent to two sides of the gate structure 26, in which the metal routing (not shown) including metal interconnections and antenna connected to the source/drain region 28 on left side of the gate structure 26 is not only symmetrical to the metal routing 136 and antenna 142 connected to the source/drain region 28 on right side of the gate structure 26, but also symmetrical to the metal routing 36 and antenna 42 connected to the gate structure 26. In other words, the present embodiment includes three sets of symmetrical metal routings and antennae that are connected to the gate structure 26 and source/drain regions 28 adjacent to two sides of the gate structure 26.

According to an embodiment of the present invention, the sum of all the top surface area of all the contact plugs 132 connected to the source/drain regions 28 and all the top surface area of all the contact plugs 32 connected to the gate structure 26 divided by the top surface of the gate structure 26 itself could be less than a ratio, equal to a ratio, or between a range of ratios, such as less than 200, equal to 200, between 150-200, or between 180-220. Preferably, all the contact plugs connected to the source/drain regions 28 include the contact plugs 132 connected to the source/drain region 28 adjacent to right side of the gate structure 26 and the contact plugs 132 connected to the source/drain region 28 adjacent to left side of the gate structure 26.

According to an embodiment of the present invention, the sum of all the top surface area of all the first level metal interconnection 138 made of trench conductors connected to the source/drain regions 28 and all the top surface area of all the first level metal interconnection 38 made of trench conductors connected to the gate structure 26 divided by the top surface of the gate structure 26 itself could be less than a ratio, equal to a ratio, or between a range of ratios, such as less than 200, equal to 200, between 150-200, or between 180-220. Preferably, all the first level metal interconnection made of trench conductors connected to the source/drain regions 28 include the first level metal interconnection 138 connected to the source/drain region 28 adjacent to right side of the gate structure 26 as shown in FIG. 2 and metal interconnection connected to the source/drain region 28 adjacent to left side of the gate structure that is not shown in FIG. 2 but is on the same level and symmetrical to the metal interconnection 138 connected to the source/drain region 28 on right side of the gate structure 26.

According to another embodiment of the present invention, the sum of all the top surface area of all the first level metal interconnection 148 made of via conductors connected to the source/drain regions 28 and all the top surface area of all the first level metal interconnection 48 made of via conductors connected to the gate structure 26 divided by the top surface of the gate structure 26 itself could be less than a ratio, equal to a ratio, or between a range of ratios, such as less than 200, equal to 200, between 150-200, or between 180-220. Preferably, all the first level metal interconnection made of via conductors connected to the source/drain regions 28 include the first level metal interconnection 148 connected to the source/drain region 28 adjacent to right side of the gate structure 26 as shown in FIG. 2 and metal interconnection connected to the source/drain region 28 adjacent to left side of the gate structure that is not shown in FIG. 2 but is on the same level and symmetrical to the metal interconnection 148 connected to the source/drain region 28 on right side of the gate structure 26.

According to yet another embodiment of the present invention, the sum of all the top surface area of all the second level metal interconnection 152 made of via conductors connected to the source/drain regions 28 and all the top surface area of all the second level metal interconnection 52 made of via conductors connected to the gate structure 26 divided by the top surface of the gate structure 26 itself could be less than a ratio, equal to a ratio, or between a range of ratios, such as less than 200, equal to 200, between 150-200, or between 180-220. Preferably, all the second level metal interconnection made of via conductors connected to the source/drain regions 28 include the second level metal interconnection 152 connected to the source/drain region 28 adjacent to right side of the gate structure 26 as shown in FIG. 2 and metal interconnection connected to the source/drain region 28 adjacent to left side of the gate structure that is not shown in FIG. 2 but is on the same level and symmetrical to the metal interconnection 152 connected to the source/drain region 28 on right side of the gate structure 26.

Overall, the present invention provides a method for determining antenna rule for RF device so that when charges collected by antenna over accumulates thereby resulting in damage to the gate dielectric layer made of silicon oxide could be prevented. According to a preferred embodiment of the present invention, a sum of the area of the metal routing connected to the source/drain regions and the area of the metal routing connected to the gate structure divided by the area of the gate structure itself is less than a ratio, equal to a ratio, or between a range of ratios, such as less than 200, equal to 200, between 150-200, or between 180-220. Preferably, the metal routing area connected to the source/drain regions could include all the top surface area of contact plugs on the same level connected to the source/drain regions or all the top surface area of metal interconnections on the same level connected to the source/drain regions. The metal routing area connected to the gate structure on the other hand could include all the top surface area of contact plugs on the same level connected to the gate structure or all the top surface are of metal interconnections on the same level connected to the gate structure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for determining antenna rule for a radio-frequency (RF) device, comprising:
forming a gate structure on a substrate;
forming a source/drain region adjacent to the gate structure;
forming a first metal routing on the source/drain region; and
forming a second metal routing on the gate structure, wherein a sum of an area of the first metal routing and an area of the second metal routing divided by an area of the gate structure is less than a ratio.

2. The method of claim 1, wherein forming the first metal routing and the second metal routing comprises:
forming a first contact plug on the source/drain region;
forming a second contact plug on the gate structure;
forming a first metal interconnection to connect the first contact plug;
forming a second metal interconnection to connect the second contact plug;
forming a first connection pole to connect the first metal interconnection; and
forming a second connection pole to connect the second metal interconnection.

3. The method of claim 2, further comprising:
forming a first antenna to connect the first connection pole; and
forming a second antenna to connect the second connection pole.

4. The method of claim 3, wherein the first antenna and the second antenna are on the same level.

5. The method of claim 3, further comprising:
forming a first pad to connect the first connection pole after forming the first antenna; and
forming a second pad to connect the second connection pole after forming the second antenna.

6. The method of claim 5, wherein the first pad and the second pad are on the same level.

7. The method of claim 2, wherein a sum of an area of the first contact plug and an area of the second contact plug divided by the area of the gate structure is less than the ratio.

8. The method of claim 2, wherein a sum of an area of the first metal interconnection and an area of the second metal interconnection divided by the area of the gate structure is less than the ratio.

9. The method of claim 1, wherein the substrate comprises a silicon-on-insulator (SOI) substrate.

10. A radio-frequency (RF) device, comprising:
a gate structure on a substrate;
a source/drain region adjacent to the gate structure;
a first metal routing on the source/drain region; and
a second metal routing on the gate structure, wherein a sum of an area of the first metal routing and an area of the second metal routing divided by an area of the gate structure is less than a ratio.

11. The RF device of claim 10, wherein the first metal routing and the second metal routing comprises:
a first contact plug on the source/drain region;
a second contact plug on the gate structure;
a first metal interconnection connecting the first contact plug;
a second metal interconnection connecting the second contact plug;
a first connection pole connecting the first metal interconnection; and
a second connection pole connecting the second metal interconnection.

12. The RF device of claim 11, further comprising:
a first antenna connecting the first connection pole; and
a second antenna connecting the second connection pole.

13. The RF device of claim 12, wherein the first antenna and the second antenna are on the same level.

14. The RF device of claim 12, further comprising:
a first pad connecting the first connection pole; and
a second pad connecting the second connection pole.

15. The RF device of claim 14, wherein the first pad and the second pad are on the same level.

16. The RF device of claim 11, wherein a sum of an area of the first contact plug and an area of the second contact plug divided by the area of the gate structure is less than the ratio.

17. The RF device of claim 11, wherein a sum of an area of the first metal interconnection and an area of the second metal interconnection divided by the area of the gate structure is less than the ratio.

18. The RF device of claim 10, wherein the substrate comprises a silicon-on-insulator (SOI) substrate.
